(19) United States
(12) Patent Application Publication
(10) Pub. No.: US 2012/0199177 A1
(43) Pub. Date: Aug. 9, 2012

(54) Multijunction Solar Cell Device

(75) Inventors: Chih-kang Chao, Taoyuan County (TW); Chih-Hung Wu, Taoyuan County (TW); Ying-Ru Chen, Taoyuan County (TW); Min-De Yang, Taoyuan County (TW); Keng-Shen Liu, Taoyuan County (TW); Chun-Ling Chang, Taoyuan County (TW)

(73) Assignee: ATOMIC ENERGY COUNCIL-INSTITUTE OF NUCLEAR ENERGY RESEARCH, Taoyuan County (TW)

(21) Appl. No.: 13/024,130

(22) Filed: Feb. 9, 2011

(51) Int. Cl. H01L 31/058; H01L 31/06

(52) U.S. Cl. 136/248; 136/255

(57) ABSTRACT

The present disclosure provides a solar cell device. The device has solar cells having multijunction. A supplemental current source is connected with one of the solar cells having a smallest current in the device. Thus, through providing required current by the supplemental current source, usage performance of the device is enhanced.

### TECHNICAL FIELD OF THE DISCLOSURE

The present disclosure relates to is solar cell; more particularly, relates to enhancing usage performance of a solar cell set through providing required current by a supplemental current source.

### DESCRIPTION OF THE RELATED ART

As shown in FIG. 8 and FIG. 9, a general solar cell set 5 comprises a plurality of multijunction solar cells 51 connected in a cascading way for receiving and transferring solar energy for destined equipments.

Although the solar cell set 5 uses solar cells 51 having multijunction, currents in the solar cells 51 varies. Usually, the current of the solar cell 51 on top has the smallest current. Therefore, on transferring the current, performance of the solar cell set 5 is limited by the solar cell 51 having the smallest current as power equals to the product of multiplying current with voltage. Hence, the prior art does not fulfill all users' requests on actual use.

### SUMMARY OF THE DISCLOSURE

The main purpose of the present disclosure is to enhance usage performance of a solar cell set through providing required current by a supplemental current source.

To achieve the above purpose, the present disclosure is a multijunction solar cell device, comprising a solar cell set and a supplemental current source, where the solar cell set comprises a plurality of multijunction solar cells; the multijunction solar cells are stacked in a cascading way; and the supplemental current source is connected with a multijunction solar cell having a smallest current in the solar cell set. Accordingly, a novel multijunction solar cell device is obtained.

### BRIEF DESCRIPTIONS OF THE DRAWINGS

The present disclosure will be better understood from the following detailed descriptions of the preferred embodiments according to the present disclosure, taken in conjunction with the accompanying drawings, in which

FIG. 1 is the structural view showing the first preferred embodiment according to the present disclosure;

FIG. 2 is the view showing the equivalent circuit of the first preferred embodiment;

FIG. 3 is the structural view showing the second preferred embodiment according to the present disclosure;

FIG. 4 is the view showing the equivalent circuit of the second preferred embodiment;

FIG. 5 is the top-down view showing the solar cell set with pyramidal carrier;

FIG. 6 is the perspective view showing the solar cell set with pyramidal carrier;

FIG. 7 is the top-down view showing the solar cell set with planar carrier;

FIG. 8 is the view of the prior art; and

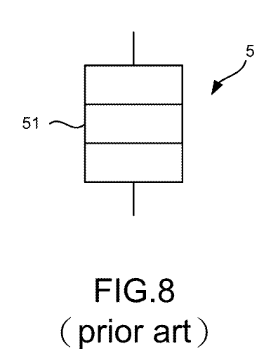

FIG. 9 is the view of the equivalent circuit of the prior art.

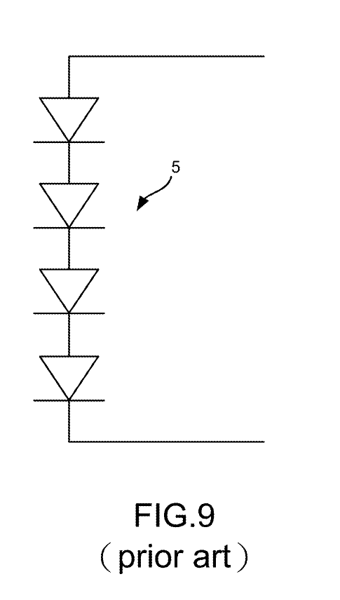

### DESCRIPTION OF THE PREFERRED EMBODIMENTS

The following descriptions of the preferred embodiments are provided to understand the features and the structures of the present disclosure.

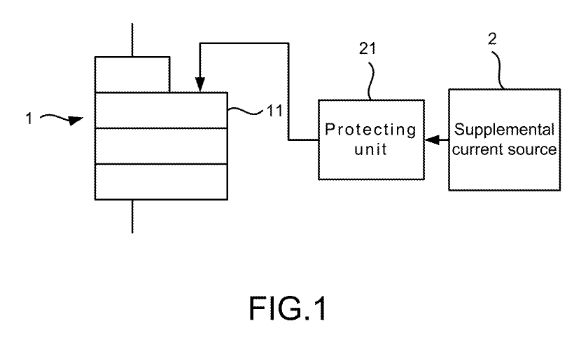

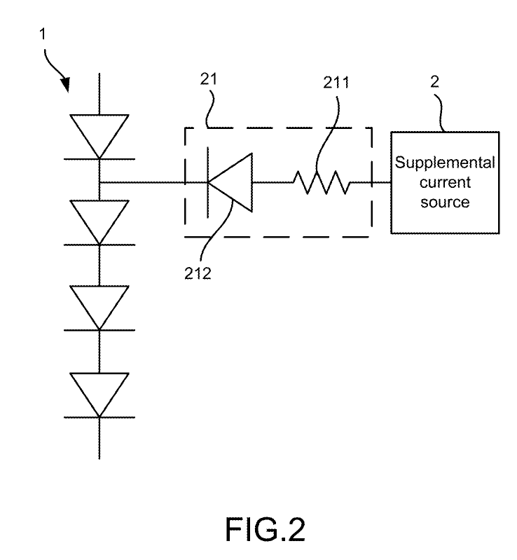

Please refer to FIG. 1 and FIG. 2, which are a structural view showing a first preferred embodiment according to the present disclosure; and a view showing an equivalent circuit of the first preferred embodiment. As shown in the figures, the present disclosure is a multijunction solar cell device, comprising a solar cell set 1 and a supplemental current source 2, where the supplemental current source 2 is used to supplement current for enhancing usage performance of the solar cell set 1.

The solar cell set 1 is a single solar cell and comprises a plurality of multijunction solar cells 11 stacked in a cascading way.

The supplemental current source 2 is electrically connected with a multijunction solar cell 11 having a smallest current in the solar cell set 1. Therein, the supplemental current source 2 is a source supplied by an external power supply; and the supplemental current source is further connected with a protecting unit 21. The protecting unit 21 comprises a resistance 211 and a diode 212. The resistance 211 is an accurate ceramic electric resistance or a variable electric resistant. The diode 212 is a PN diode or is simulated by transistor. Thus, a novel multijunction solar cell device is obtained.

On using the present disclosure, the supplemental current source 2 supplies a current to a multijunction solar cell 11 having the smallest current in the solar cell set 1 through the protecting unit 21. Since power (P) is a product of multiplying voltage (V) with current (I), current will be increased when the current is supplied to the multijunction solar cell 11 having the smallest current in the solar cell set 1; and, thus, by supplying the current to the multijunction solar cell 11 having the smallest current in the solar cell set 1, power and efficiency of the solar cell set 1 are both enhanced.

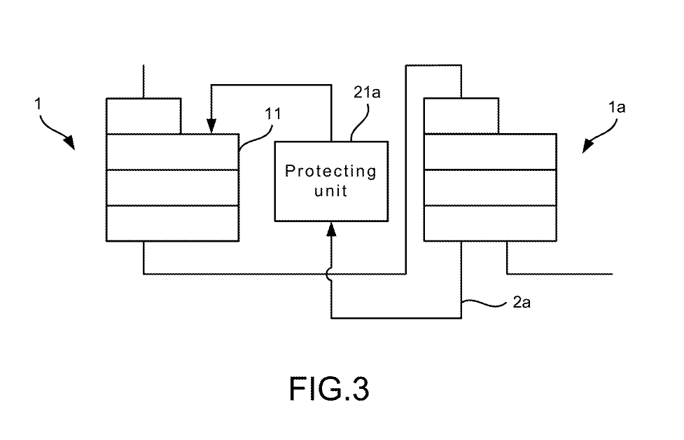

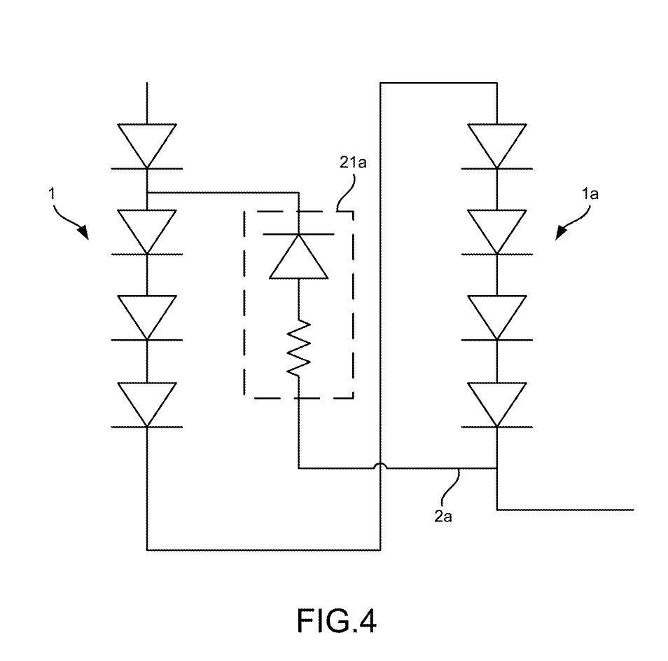

Please refer to FIG. 3 and FIG. 4, which are a structural view showing a second preferred embodiment according to the present disclosure; and a view showing an equivalent circuit of the second preferred embodiment. As shown in the figures, on using the present disclosure, a first solar cell set and a second solar cell set 1a are used with serial connection. A supplemental current source 2a is supplied by the second solar cell set 1a, where the supplemental current source 2a supplied by the second solar cell set 1a is directly connected with the multijunction solar cell 11 having the smallest current in the first solar cell set 1. Thus, through providing required current to the first solar cell set 1 by the supplemental current source 2a coordinated with a protecting unit 21a, performance of the first solar cell set 1 is enhanced for usage.

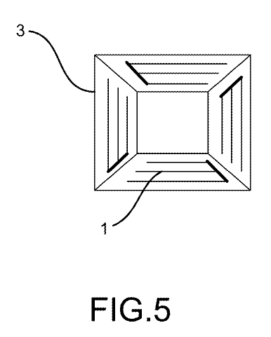

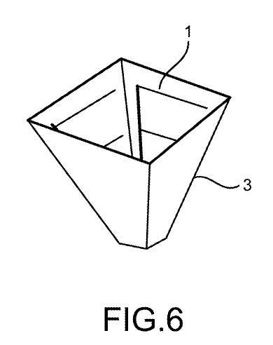

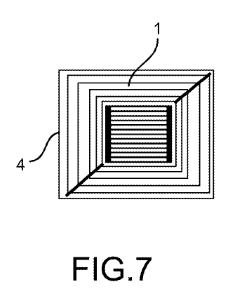

Please refer to FIG. 5 to FIG. 7, which are a top-down view showing the solar cell set with pyramidal carrier; a perspective view showing the solar cell set with pyramidal carrier; and a top-down view showing the solar cell set with planar carrier. As shown in the figures, a solar cell set 1 according to the present disclosure can be set on a pyramidal carrier 3 or a planar carrier 4 for achieving reduced cost and enhanced energy usage.

To sum up, the present disclosure is a multijunction solar cell device, where usage performance of a solar cell set is enhanced through providing required current by a supplemental current source.

The preferred embodiments herein disclosed are not intended to unnecessarily limit the scope of the disclosure. Therefore, simple modifications or variations belonging to the equivalent of the scope of the claims and the instructions disclosed herein for a patent are all within the scope of the present disclosure.

What is claimed is:

1. A multijunction solar cell device, comprising:
a solar cell set, said solar cell set comprising a plurality of multijunction solar cells, said multijunction solar cells being stacked in a cascading way; and
a supplemental current source, said supplemental current source being connected with a multijunction solar cell having a smallest current in said solar cell set.

2. The multijunction solar cell device according to claim 1,
wherein said solar cell set is a single solar cell.

3. The multijunction solar cell device according to claim 1,
wherein said solar cell set comprises a plurality of solar cells serially connected.

4. The multijunction solar cell device according to claim 1,
wherein said supplemental current source is supplied by an external power supply.

5. The multijunction solar cell device according to claim 1,
wherein said supplemental current source is supplied by another solar cell set.

6. The multijunction solar cell device according to claim 1,
wherein said supplemental current source is connected with a protecting unit; and
wherein said protecting unit comprises a resistance and a diode.

7. The multijunction solar cell device according to claim 6,
wherein said resistance is an accurate ceramic electric resistance.

8. The multijunction solar cell device according to claim 6,
wherein said resistance is a variable electric resistant.

9. The multijunction solar cell device according to claim 6,
wherein said diode is a PN diode.

10. The multijunction solar cell device according to claim 6,
wherein said diode is simulated by transistor.
